(19) United States
(12) Patent Application Publication
(10) Pub. No.: US 2002/0033730 A1
(43) Pub. Date: Mar. 21, 2002

(54) Preset circuit and method for n-well bias of a CMOS circuit

(76) Inventors: Chi-Tai Yao, Kaohsiung Hsien (TW); Wei-Chen Shen, Hsinchu (TW); Hung Chih Liu, Hsinchu (TW)

Correspondence Address: @@ Michael P. Dunnam, Esq., WOODCOCK WASHBURN KURTZ, MACKIEWICZ & NORRIS LLP, One Liberty Place - 46th Floor, Philadelphia, PA, 19103, US

(21) Appl. No.: 09/749,996

(22) Filed: Dec. 28, 2000

(30) Foreign Application Priority Data
Sep. 15, 2000 (TW) 89118956

(51) Int. Cl. H03L 7/00

(52) U.S. Cl. 327/534; 327/143

(57) ABSTRACT

The present invention discloses an n-well bias preset circuit and method. The present invention electrically connects an n-well bias point of the n-well region to the power at the power-on moment to avoid latch-up effect in the CMOS circuit. After several cycles, the n-well bias point is separated from the power, and electrically connected to the output of the n-well bias circuit for reducing the body effect of the CMOS circuit.

### BACKGROUND OF THE INVENTION

1. Field of the Invention

The present invention relates to a circuit and method for an n-well bias of a CMOS circuit, and particularly to a preset circuit and method for n-well bias of a CMOS circuit at the power-on transient.

2. Description of Related Art

FIG. 1 shows a prior art CMOS circuit 11 that comprises a pair of current switches and cascode-connected transistors constituting transistors 15 and 16. The n-well regions of the transistors 13 and 14 are electrically connected to each other, and controlled by an n-well bias point VBNW. The voltage magnitude of the n-well bias point VBNW is less than that of the power for reducing the body effect and threshold voltage of the transistors 13 and 14. There is an application problem with the CMOS circuit 11 that since an initial voltage of the source terminals 12 of the transistors 13 and 14 is unknown at the power-on moment, and a latch-up effect will be created to bum down the transistors.

FIG. 2 shows another prior art CMOS circuit 21. Similarly, at the power-on moment, the voltage magnitude of the drain terminals 24 of the transistors 22 and 23 is unknown, and a latch-up effect will be created to bum down the transistors.

### SUMMARY OF THE INVENTION

The object of the present invention is to eliminate the disadvantage of burning down the transistors caused by a latch-up effect in the structure of a CMOS circuit using an n-well bias circuit to control the n-well region at the power-on moment. For achieving the above objects, the present invention proposes an n-well bias preset circuit and method which electrically connects an n-well bias point of the CMOS circuit to the power at the power-on moment to avoid latch-up effect in the CMOS circuit. After several cycles, the n-well bias point is separated from the power, and electrically connected to the output of the n-well bias circuit for reducing the body effect of the CMOS circuit.

The preset circuit for the n-well bias of a CMOS circuit according to the present invention comprises a power-on detecting module, an n-well bias circuit and a switching module. The power-on detecting module is used to detect if the power of the CMOS circuit is turned on. The n-well bias circuit is used to generate an output whose voltage magnitude is less than that of the power. The switching module is connected to the power-on detecting module and the n-well bias circuit. When said power-on detecting module finds out that the power of the CMOS circuit has been turned on, said switching module electrically connects the power to an n-well bias point of the CMOS circuit to avoid a latch-up effect occurring in the CMOS circuit, separates the power from the n-well bias point after several cycles, and electrically connects the output of the n-well bias circuit to the n-well bias point for reducing the body effect occurring in the CMOS circuit.

The preset method for an n-well bias of a CMOS circuit according to the present invention comprises step (a) to step (c). In step (a), whether the power of the CMOS circuit is turned on is determined. In step (b), if the answer in step (a) is no, then keeps the detection. Otherwise, the power is electrically connected to an n-well bias point of the CMOS circuit to avoid a latch-up effect occurring in the CMOS circuit. In step (c), after several cycles, the power is separated from the n-well bias point, and an output whose voltage magnitude is less than that of the power is electrically connected to the n-well bias point for reducing the body effect of the CMOS circuit.

### BRIEF DESCRIPTION OF THE DRAWINGS

The present invention will be described according to the appended drawings in which:

FIG. 1 shows a prior art CMOS circuit;

FIG. 2 shows another prior art CMOS circuit;

FIG. 3 is a schematic diagram of the n-well bias preset circuit of a CMOS circuit according to the present invention;

FIG. 4 shows one embodiment of the n-well bias preset circuit of a CMOS circuit according to the present invention;

FIG. 5 shows a prior art unit cell of the n-well bias circuit in a CMOS circuit;

FIG. 6 show a flow chart according to the present invention; and

FIGS. 7(a) and (b) show output curves of the n-well bias preset circuit of a CMOS circuit according to the present invention.

### PREFERRED EMBODIMENT OF THE PRESENT INVENTION

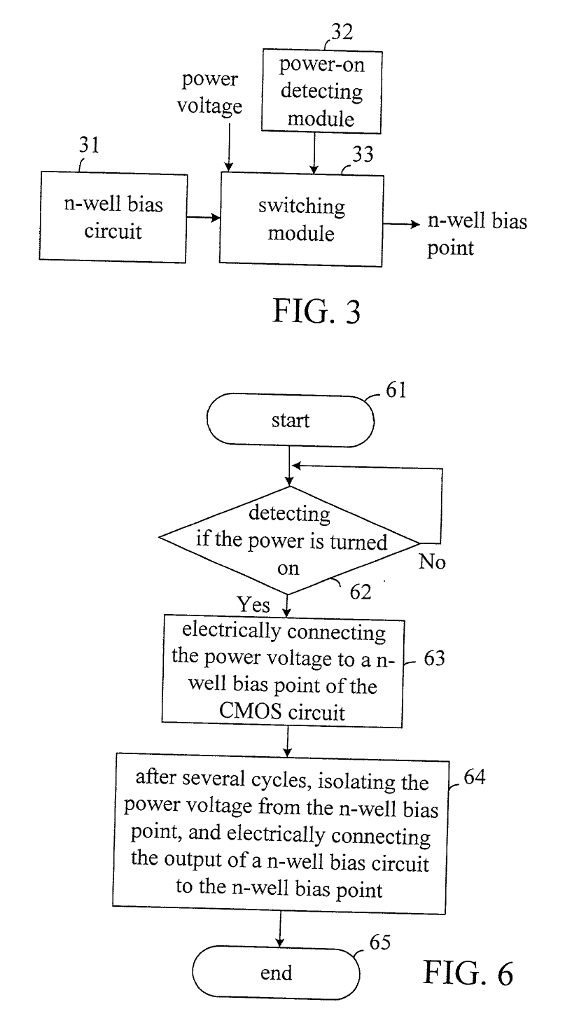

FIG. 3 is a schematic diagram of the n-well bias preset circuit of a CMOS circuit according to the present invention. The n-well bias preset circuit comprises an n-well bias circuit 31, a power-on detecting module 32 and a switching module 33. The power-on detecting module is used to detect if the power of a CMOS circuit is turned on. The n-well bias circuit 31 is used to generate an output whose voltage magnitude is less than that of the power. If the power-on detecting module 32 detects that the power of the CMOS circuit has been turned on, the switching module 33 electrically connects the n-well bias point to the power to avoid latch-up effect happened in the CMOS circuit. After several cycles, the switching module 33 separates the n-well bias point from the power by outputting high impedance and electrically connects the output of the n-well bias circuit 31 to the n-well bias point to reduce the body effect created in the CMOS circuit. Equation (1) is a well-known formula to avoid latch-up effect. If the inequality is sustained, the latch-up effect will be avoided.

V_{S}<V_{n-well}+|Vₜₕ| (1)

Wherein V_{S} is the drain terminal voltage of a transistor, V_{N-well} is the voltage of the n-well region, and |Vₜₕ| is the absolute value of the threshold voltage of the CMOS circuit.

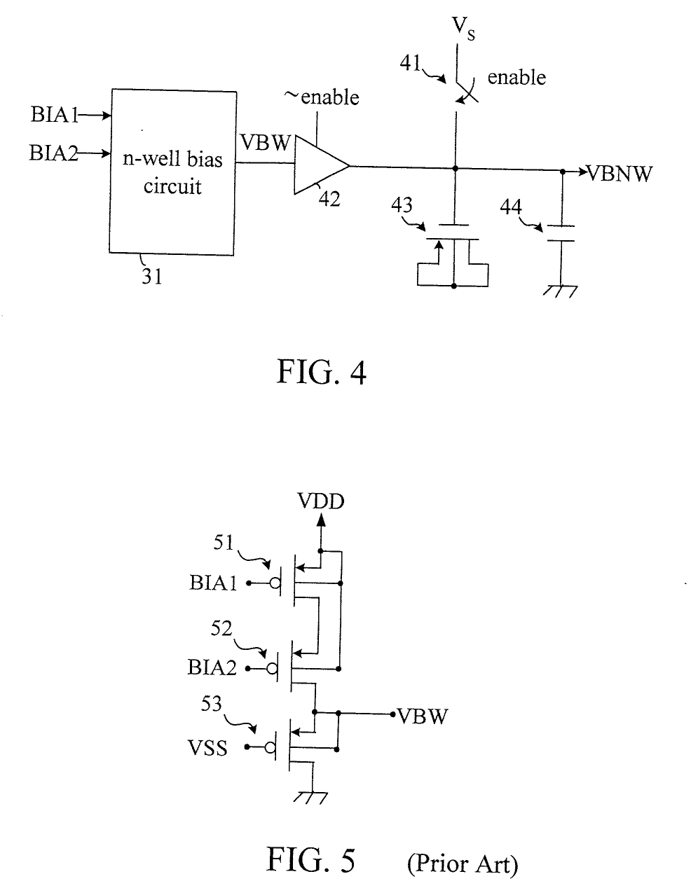

FIG. 4 shows one embodiment of the n-well bias preset circuit of a CMOS circuit according to the present invention. The n-well bias point VBNW has two multiplexing input signals, i.e., power voltage V_{S} and the output VBW of the n-well bias circuit 31. First, if the power-on detecting module 32 finds out that the power of the CMOS circuit is turned on, the enable signal is set to logic one, a switch 41 is close, and a voltage follower 42 is disabled. Meanwhile, the n-well bias point VBNW is controlled by the power voltage, and thus a latch-up effect occurring at the power-on moment will be prevented. After several cycles, the enable signal is set to logic zero, the switch 41 is open, and the voltage follower 42 is enabled. Meanwhile, the n-well bias point VBNW is controlled by the output VBW of the n-well bias circuit 31. As the magnitude of the output voltage VBW of the n-well bias circuit 31 is less than that of the power voltage, the body effect and threshold voltage of the CMOS circuit would be reduced. The n-well bias point VBNW is further connected to an on-chip capacitor 43 or an external capacitor 44 for stabilizing voltage, such as reducing noise interference while voltage switching.

FIG. 5 shows a prior art unit cell of the n-well bias circuit of a CMOS circuit, wherein the unit cell is formed by three transistors 51˜53. The gate terminal of a first transistor 53 is electrically connected to ground VSS. Transistors 51 and 52 referred to as cascode-connected transistors (in practical application, the number of the cascode-connected transistors could be adjusted according to different demands), whose gate terminals are respectively electrically connected to bias voltages BIA1 and BIA2. The source terminal and the n-well region of the first transistor 53 are electrically connected to each other to output a bias voltage VBW. The n-well bias circuit 31 can use the structure of the three transistors 51˜53 as a basic unit to be duplicated.

FIG. 6 shows a flow chart according to the present invention. In step 61, the present invention starts. In step 62, if the power of a CMOS circuit is turned on is detected. If the answer is yes, then enter step 63; otherwise enter step 62 to keep detecting. In step 63, the n-well bias point of the CMOS circuit is electrically connected to the power. After several cycles, the flow enters step 64. In step 64, the n-well bias point is separated from the power, and the output VBW of an n-well bias circuit is electrically connected to the n-well bias point. In step 65, the flow ends.

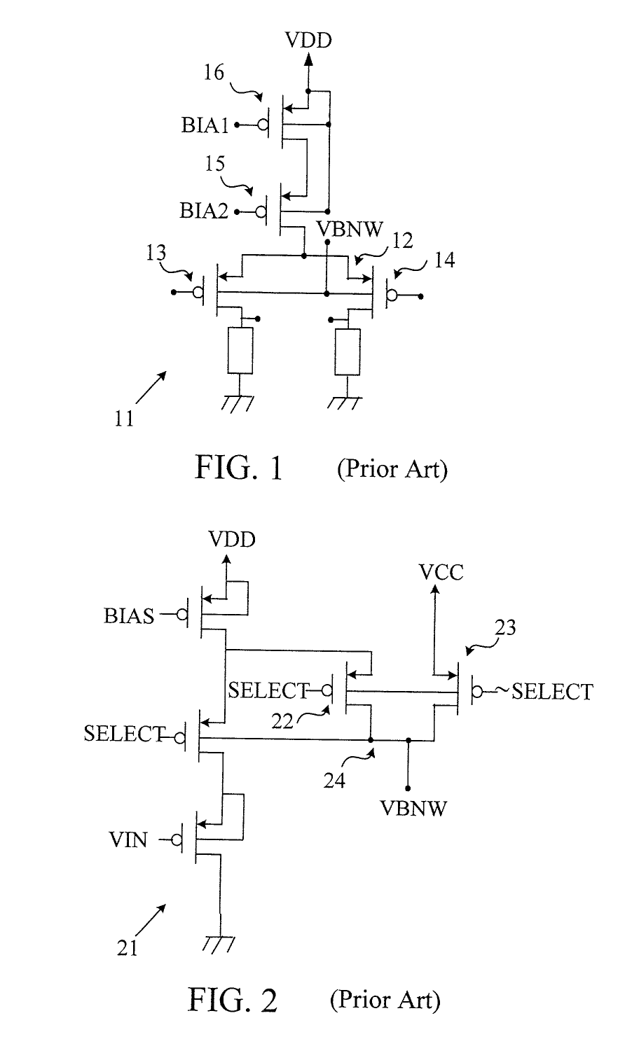

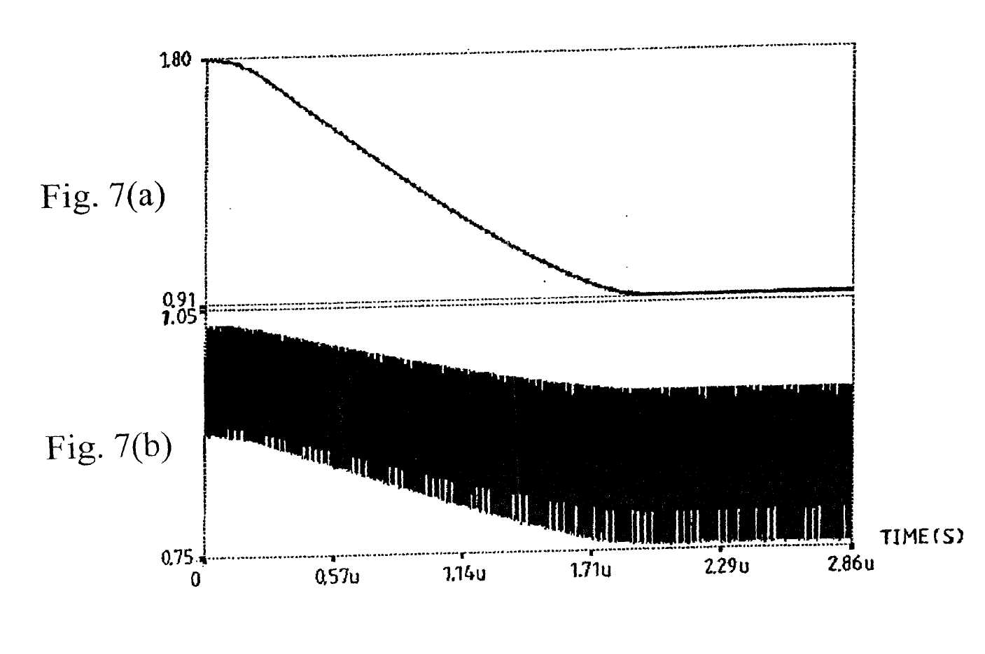

FIGS. 7(a) and 7(b) show output curves of the n-well bias preset circuit of a CMOS circuit according to the present invention, wherein FIG. 7(a) shows an output voltage curve of the n-well bias point of the CMOS circuit 11 in FIG. 1, and FIG. 7(b) shows an output voltage curve of the source terminals 12 of the transistors 13 and 14 of the CMOS circuit 11 shown in FIG. 1. In FIG. 7(b), as signal transitions are densely created, the output curve is similar to a black strip in a large time domain. The simulation conditions in FIGS. 7(a) and 7(b) are 0.18 μm line width, 400 MHz clock frequency, 1.8V power voltage, and measured in the n-well region of the CMOS circuit. It can be found in FIG. 7(a) that the output voltage curve of the n-well bias point VBNW fluctuates between 1.05V and 0.75V. If the threshold voltage is 0.4V, according to equation (1), the present invention will prevent the latch-up effect at the power-on moment in order to increase the reliability of the CMOS circuit.

The above-described embodiments of the present invention are intended to be illustrated only. Numerous alternative embodiments may be devised by those skilled in the art without departing from the scope of the following claims.

What is claimed is:

1. A preset circuit for an n-well bias of a CMOS circuit, comprising:
a power-on detecting module for detecting if the power of the CMOS circuit is turned on;
an n-well bias circuit for generating an output whose voltage magnitude is less than that of the power; and
a switching module connected to the power-on detecting module and the n-well bias circuit; wherein when said power-on detecting module finds out that the power of the CMOS circuit has been turned on, said switching module electrically connects the power to an n-well bias point of the CMOS circuit to avoid a latch-up effect occurring in the CMOS circuit, separates the power from the n-well bias point after several cycles, and electrically connects the output of the n-well bias circuit to the n-well bias point for reducing the body effect occurring in the CMOS circuit.

2. The preset circuit for an n-well bias of a CMOS circuit of claim 1, wherein said n-well bias circuit includes a plurality of unit cells, and each of said unit cells comprises:
at least one cascode-connected transistor, the n-well region of said at least one cascode-connected transistor electrically connected to said power; and
a first transistor, whose gate terminal and drain terminal being electrically connected to ground, wherein the source terminal of said first transistor is electrically connected to the drain terminal of one of said at least one cascode-connected transistor, and the n-well region of said first transistor is electrically connected to the source terminal of said first transistor to form an output node.

3. The preset circuit for an n-well bias of a CMOS circuit of claim 1, wherein said n-well bias point is further electrically connected to at least one capacitor for stabilizing voltage.

4. A preset circuit for an n-well bias of a CMOS circuit, comprising:
a power-on detecting module for detecting if the power of the CMOS circuit is turned on;
an n-well bias circuit for generating an output whose voltage magnitude is less than that of the power;
a switching module connected to the power-on detecting module and the power; wherein when said power-on detecting module finds out that the power of the CMOS circuit has been turned on, said switching module electrically corrects the power to an n-well bias point of the CMOS circuit, and cuts off the connection between the power and the n-well bias point of the CMOS circuit after several cycles; and
a voltage buffer connected to said power-on detecting module and n-well bias circuit; wherein when the power is turned on, a high impedance state is created and after several cycles, the output of said n-well bias circuit is transferred to the n-well bias point.

5. The preset circuit for an n-well bias of a CMOS circuit of claim 4, wherein said n-well bias point is further electrically connected to at least one capacitor for stabilizing voltage.

6. A preset method for an n-well bias of a CMOS circuit, comprising the following steps of:
(a) detecting if the power of the CMOS circuit is turned on;
(b) if the answer in step (a) is no, then keeping the detection; otherwise electrically connecting the power to an n-well bias point of the CMOS circuit to avoid a latch-up effect occurring in the CMOS circuit; and
(c) after several cycles, separating the power from the n-well bias point, and electrically connecting an output whose voltage magnitude is less than that of the power to the n-well bias point for reducing the body effect of the CMOS circuit.
